(19) United States
(12) Patent Application Publication
(10) Pub. No.: US 2008/0141527 A1
(43) Pub. Date: Jun. 19, 2008

(54) METHOD FOR MANUFACTURING MULTILAYER FLEXIBLE PRINTED CIRCUIT BOARD

(75) Inventors: CHENG-HSIEN LIN, Tayuan (TW); WEN-CHIN LEE, Tayuan (TW)

Correspondence Address: PCE INDUSTRY, INC.;ATT. CHENG-JU CHIANG, 458 E. LAMBERT ROAD, FULLERTON, CA, 92835, US

(73) Assignee: FOXCONN ADVANCED TECHNOLOGY INC., Tayuan (TW)

(21) Appl. No.: 11/861,650

(22) Filed: Sep. 26, 2007

(30) Foreign Application Priority Data
Dec. 13, 2006 (CN) 200610157606.1

(51) Int. Cl. H05K 3/46

(52) U.S. Cl. 29/846; 29/829; 29/830

(57) ABSTRACT

The present inventions relates to a method for manufacturing a multilayer FPCB. The method includes the steps of providing three copper clad laminates and two binder layers, each of the copper clad laminates includes a dielectric layer and at least one patterned conductive layer formed on the dielectric layer; stacking the copper clad laminates and the binder layers alternately one on another; aligning the copper clad laminates and the binder layers; and compressing the copper clad laminates and the binder layers together thereby obtaining a multilayer flexible printed circuit board.

### BACKGROUND

1. Technical Field

The present invention relates to a method for manufacturing a flexible printed circuit board, and especially relates to a method for manufacturing a multilayer flexible printed circuit board having different numbers of layers in different areas.

2. Discussion of Related Art

Flexible printed circuit boards (FPCB) have been widely used in electronic products such as mobile phones, printing heads and hard disks. In these electronic products, some parts may move relative to a main body. FPCB can assure power supply and signal transmission in such environment due to their excellent flexibility.

FIG. 8 shows a typical process for manufacturing a multilayer FPCB. Two copper clad laminates 82 and a binder layer 84 are provided. Conductive patterns are formed on the two copper clad laminates 82. The two copper clad laminates 82 are stacked and laminated thereby forming a dual layered FPCB structure. Additional copper clad laminates 86 are provided, stacked and laminated on the dual layered FPCB structure thereby forming a quadrilayered FPCB structure. Similar processes can be repeated until a predetermined number of layers are obtained.

In this kind of process, multiple laminating steps are required thus lengthening processing time, and positioning errors may occur between different copper clad laminates. These positioning errors may cause short circuits when conductive through holes are formed on the FPCB.

Therefore it is desired to develop a method for manufacturing a multilayer FPCB in which multiple laminating steps can be avoided.

### SUMMARY

In one embodiment, a method for manufacturing a multilayer flexible printed circuit board, the method includes steps of: providing three copper clad laminates and two binder layers, each of the copper clad laminates comprising a dielectric layer and at least one patterned conductive layer formed on the dielectric layer; stacking the copper clad laminates and the binder layers in alternating fashion one on another; aligning the copper clad laminates and the binder layers; and compressing the copper clad laminates and the binder layers together thereby obtaining a multilayer flexible printed circuit board.

### BRIEF DESCRIPTION OF THE DRAWINGS

Many aspects of the present invention can be better understood with reference to the following drawings. The components in the drawings are not necessarily drawn to scale, the emphasis instead being placed upon clearly illustrating the principles of the present invention.

FIG. 1 is a flow chart of a method for manufacturing a multilayer FPCB;

FIGS. 2 to 4 are schematic views showing a method for manufacturing a multilayer FPCB in accordance with the first embodiment;

FIG. 5 is a schematic view showing a method for manufacturing a multilayer FPCB in accordance with the second embodiment;

FIGS. 6 and 7 are schematic views showing a method for manufacturing a multilayer FPCB in accordance with the third embodiment; and

FIG. 8 is a schematic view showing a method for manufacturing a multilayer FPCB according to related art.

### DETAILED DESCRIPTION OF THE PREFERRED EMBODIMENTS

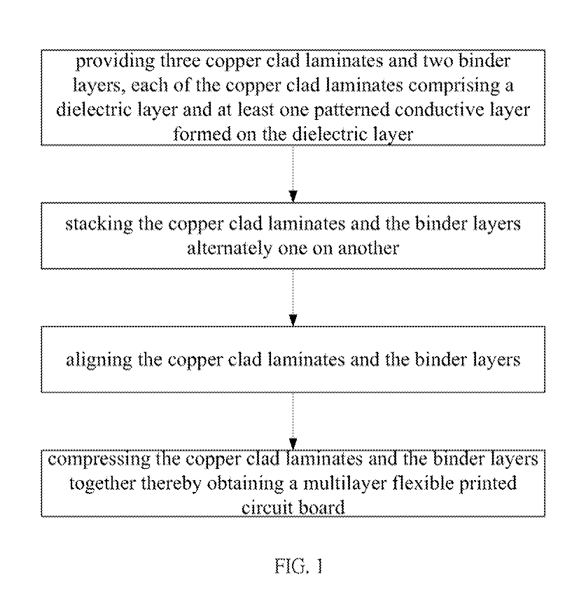

FIG. 1 shows a method for manufacturing a multilayer FPCB. The method includes steps in no particular order of: providing three copper clad laminates and two binder layers, each of the copper clad laminates comprising a dielectric layer and at least one patterned conductive layer formed on the dielectric layer; stacking the copper clad laminates and the binder layers alternately one on another; laminating the at least three copper clad laminates and the at least two binder layers in one laminating step; aligning the copper clad laminates and the binder layers; and compressing the copper clad laminates and the binder layers together thereby obtaining a multilayer flexible printed circuit board.

Each steps of the method will be described in detail with the following embodiments.

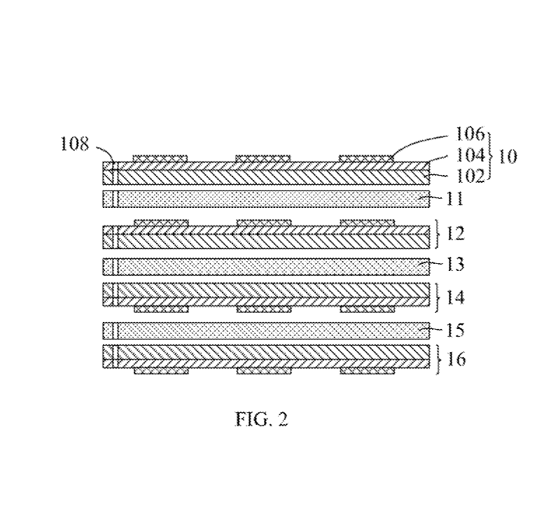

As an example, the present embodiment exemplarily discloses a method for making a quadrilayer flexible printed circuit board. Referring to FIG. 2, four copper clad laminates 10, 12, 14, 16 and three binder layers 11, 13, 15 are provided. Each copper clad laminate 10 includes a dielectric layer 102, a bonding layer 104 and a conductive pattern 106. Typically, the conductive pattern 106 is made of copper, but other metals such as silver, aluminum may also be used. The bonding layer 104 bonds the conductive layer 106 and the dielectric layer 102. A positioning hole 108 can be formed in the copper clad laminate 10. The dielectric layer 102 and the binder layers 11, 13, 15 can be made of a material selected from the group consisting of polyimide, polyimide, teflon, polythiamine, polymethacrylic acid, polycarbonate, polycarbonate ester, polyester, and copolymer of imide, ethylene and dimethyl terephthate.

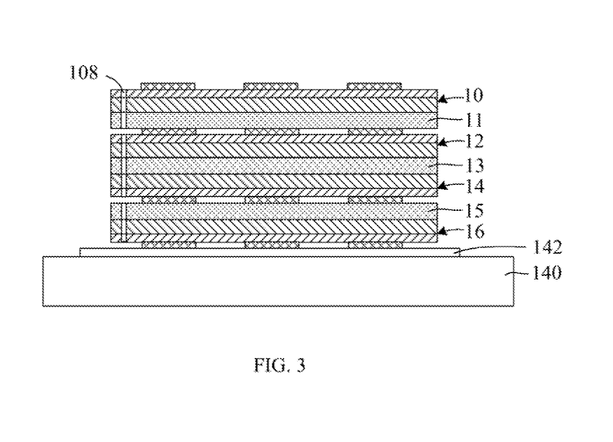

Referring to FIG. 3, the four copper clad laminates 10, 12, 14, 16 and the three binder layers 11, 13, 15 are stacked on a base 14 one on another in an alternating fashion. A protective layer 142 can be placed on the base 14 for preventing the lowest copper clad laminates 16 from directly contacting with the base 14. The base 14 can be a part of a laminating machine. Preferably, positioning holes 108 can be pre-formed on the copper clad laminates 10, 12, 14 and 16. The position holes can be used to align the copper clad laminates 10, 12, 14 and 16.

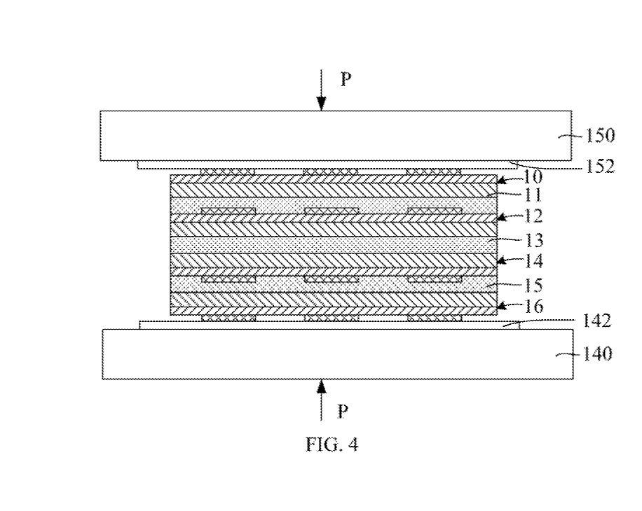

Referring to FIG. 4, a top plate 15 is attached to a top copper clad laminate 10 such that the four copper clad laminates 10, 12, 14, 16 are sandwiched between the top plate 150 and the base 140. Preferably, a protective layer 152 can be placed on the copper clad laminate 10 for preventing the highest copper clad laminate 10 from directly contacting with the top plate 15. A pressure P is applied between the base 140 and the top plate 150, the stacked four copper clad laminates 10, 12, 14, 16 and the three binder layers 11, 13, 15 are laminated together, thus obtaining a multilayer FPCB. During the lamination, the four copper clad laminates 10, 12, 14, 16 and the three binder layers 11, 13, 15 are heated to a temperature of about 180 to 200 degrees centigrade, and preferably to about 190 degrees centigrade. Preferably, this step includes substeps of pre-compressing the copper clad laminates and binder layers for a first period of time so as to soften the binder layers, and compressing the copper clad laminates and the binder layers for a second period of time. The binder layers 11, 13, 15 are softened due to the pressure and the elevated temperature in the pre-compressing step, and then the softened binder layers 11, 13, 15 fill all gaps in the stacked four copper clad laminates 10, 12, 14, 16 and the three binder layers 11, 13, 15 in the compressing step. Preferably, the duration of the first period of time is in the range form 5 to 15 seconds, the duration of the second period of time is in the range from 80 to 120 seconds.

According to this method, four copper clad laminates and three binder layers are stacked and laminated in one laminating step thus obtaining a multilayer FPCB with only one laminating step. Additional time consumption can be reduced and aligning precision can be increased. A possibility of short circuit on the conductive pattern can be avoided.

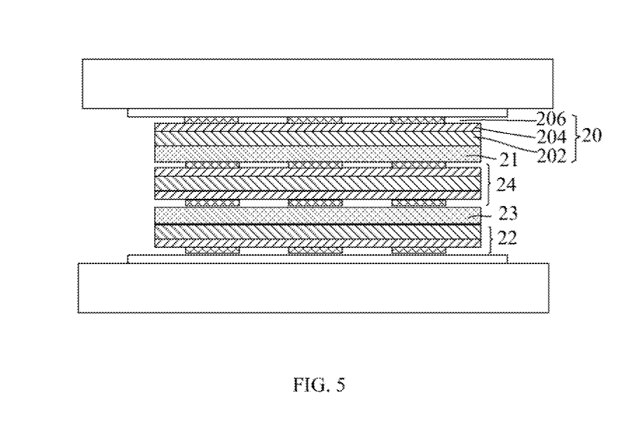

Referring to FIG. 5, a method for manufacturing a multilayer FPCB in accordance with the second embodiment is similar to that of the first embodiment except that two single-sided copper clad laminates 20, 22, a double-sided copper clad laminate 24 and two binder layers 21, 23 are provided, stacked and laminated. The single-sided copper clad laminate 20 includes a dielectric layer 202 and a conductive layer 204 formed on the dielectric layer 202. The single-sided copper clad laminate 22 has a similar structure with the single-sided copper clad laminate 20. The double-sided copper clad laminate 24 is similar to the single-sided copper clad laminate 20 except that includes two conductive layers.

In this embodiment, three copper clad laminates and two binder layers are stacked and laminated in one laminating step, thus obtaining a quadrilayered FPCB.

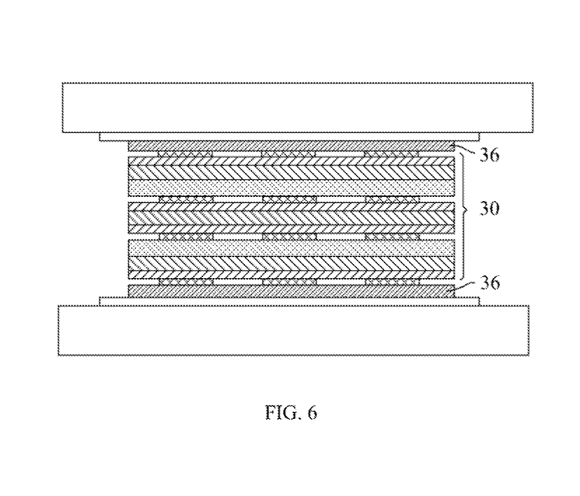

Referring to FIG. 6, a method for manufacturing a multilayer FPCB in accordance with the third embodiment is similar to that of the first embodiment except that two coverlays 36 are provided. The two coverlays 36 are disposed on two outer surfaces of the stacked copper clad laminates structure 30. As described in the second embodiment, the copper clad laminates structure 30 includes two single-side copper clad laminates, a double-sided copper clad laminate and two binder layers.

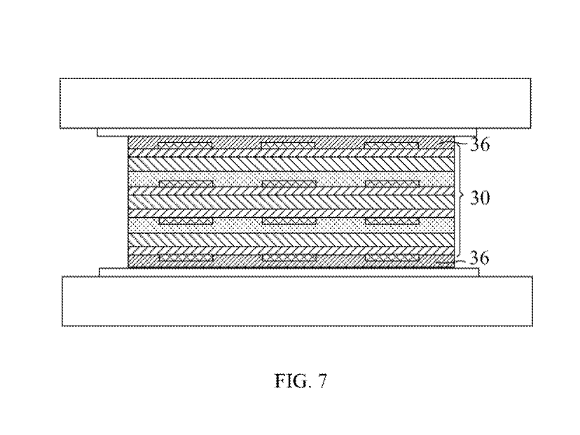

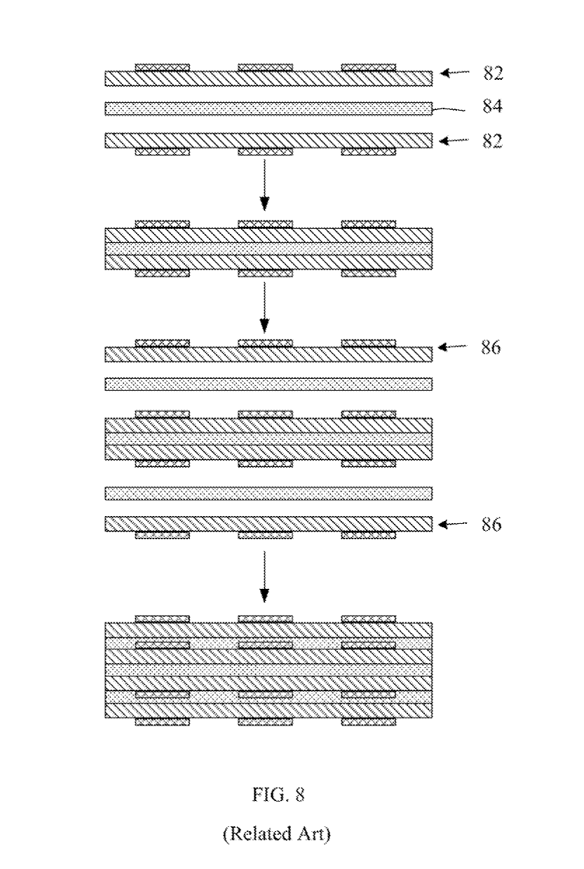

Referring to FIG. 7, the two coverlays 36 are laminated with the stacked copper clad laminates structure 30, therefore a multilayer FPCB having coverlays formed thereon is obtained by only one laminating step.

t is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A method for manufacturing a multilayer flexible printed circuit board, the method comprising steps of:
providing three copper clad laminates and two binder layers, each of the copper clad laminates comprising a dielectric layer and at least one patterned conductive layer formed on the dielectric layer;
stacking the copper clad laminates and the binder layers one on another in alternating fashion;
aligning the copper clad laminates and the binder layers; and
compressing the copper clad laminates and the binder layers together thereby obtaining a multilayer flexible printed circuit board.

2. The method as claimed in claim 1, wherein the at least one patterned conductive layer includes two patterned conductive layers formed on opposite surfaces of the dielectric layer.

3. The method as claimed in claim 1, wherein the copper clad laminates includes at least one of a single-sided copper clad laminate, and a double-sided copper clad laminate.

4. The method as claimed in claim 1, wherein the laminating step comprises substeps of pre-compressing the copper clad laminates and binder layers for a first period of time so as to soften the binder layers, and compressing the copper clad laminates and the binder layers for a second period of time.

5. The method as claimed in claim 5, wherein the first period of time is in the range from 5 to 15 seconds.

6. The method as claimed in claim 5, wherein the second period of time is in the range from 80 to 120 seconds.

7. The method as claimed in claim 1, wherein the copper clad laminates and the binder layers are heated up to a temperature of 180 to 200 degrees centigrade during the laminating step.

8. The method as claimed in claim 1, wherein a positioning hole is defined in each of the copper clad laminates and the binder layers for facilitating alignment of the copper clad laminates.
